(19) United States
(12) Patent Application Publication
(10) Pub. No.: US 2025/0076545 A1
(43) Pub. Date: Mar. 6, 2025

(54) LENS, LENS ARRAY, DISPLAYING MODULE AND DISPLAYING DEVICE

(71) Applicants: Beijing BOE Display Technology Co., Ltd., Beijing (CN); BOE Technology Group Co., Ltd., Beijing (CN)

(72) Inventors: Weining Chi, Beijing (CN); Rui Han, Beijing (CN); Daekeun Yoon, Beijing (CN); Qing Ma, Beijing (CN); Dong Cui, Beijing (CN); Zhipeng Zhang, Beijing (CN); Fengping Wang, Beijing (CN); Yue Zhai, Beijing (CN); Wenyang Li, Beijing (CN); Yongle Qi, Beijing (CN); Shouyang Leng, Beijing (CN); Biqi Li, Beijing (CN)

(73) Assignees: Beijing BOE Display Technology Co., Ltd., Beijing (CN); BOE Technology Group Co., Ltd., Beijing (CN)

(21) Appl. No.: 18/261,859

(22) PCT Filed: Aug. 31, 2022
(86) PCT No.: PCT/CN2022/116244

§ 371 Date: Jul. 18, 2023

(51) Int. Cl. G02B 3/02; H01L 25/075; H01L 33/58

(52) U.S. Cl. CPC G02B 3/02; H01L 25/0753; H10H 20/855

(57) ABSTRACT

The embodiments of the present disclosure provide a lens, a lens array, a displaying module and a displaying device. The lens includes a main lens body and a light emitting member; the main lens body is a conical housing having an inner cavity, and the light emitting member is disposed at a first end of the main lens body; a first quadric surface is disposed in the inner cavity of the main lens body; a second quadric surface is disposed on an inner wall of the main lens body; the first quadric surface is convex toward the first end of the main lens body, and the second quadric surface is convex toward a second end of the main lens body.

### TECHNICAL FIELD

The present disclosure relates to the technical field of displaying devices and, more particularly, to a lens, a lens array, a displaying module and a displaying device.

### BACKGROUND

With the continuous development of displaying devices, people are having increasingly higher requirements on the displaying of displaying devices. For example, onboard displaying devices are required to have displaying requirements of a high brightness, a high collimation degree, a low power consumption and a high contrast. The precondition of realizing a high brightness is to realize a high collimation degree, and to realize a high collimation degree requires the displaying devices to utilize all of the light rays emitted by the light source to the largest extent.

However, the light type of the light sources of the displaying modules included by the current displaying devices is generally the Lambert reflector, which simultaneously has large-angle incident light rays and small-angle incident light rays, and the small-angle light rays cannot be adjusted with the optical paths by using light-ray modulating members such as a reflection cup. Therefore, the small-angle light rays usually exit from the edge of the displaying module, which results in waste of the energy of the light source, thereby the brightness of the displaying devices is affected, and the effect of displaying of the displaying devices is reduced.

### SUMMARY

The embodiments of the present disclosure provide a lens, a lens array, a displaying module and a displaying device, to solve the problem in the related art of the waste of the energy of the light source.

In order to solve the above technical problem, the present disclosure is realized as follows:

In the first aspect, an embodiment of the present disclosure provides a lens, wherein the lens includes a main lens body and a light emitting member;

the main lens body is a conical housing having an inner cavity, and the light emitting member is disposed at a first end of the main lens body;

a first quadric surface is disposed in the inner cavity of the main lens body;

a second quadric surface is disposed on an inner wall of the main lens body;

the first quadric surface is convex toward the first end of the main lens body, and the second quadric surface is convex toward a second end of the main lens body, wherein the first end of the main lens body and the second end of the main lens body are two opposite ends of the main lens body, and the second end of the main lens body refers to one end of the main lens body where light rays exit; and

light rays emitted by the light emitting member and within a first incident-angle range pass through and are refracted by the first quadric surface, and subsequently are collimated by and exit from the second end of the main lens body, and incident light rays emitted by the light emitting member and within a second incident-angle range pass through and are reflected by the second quadric surface, and subsequently are collimated by and exit from the second end of the main lens body, wherein a maximum angle value within the first incident-angle range is less than a minimum value within the second incident-angle range, and the first incident-angle range refers to an incident-angle range corresponding to light rays that are emitted by the light emitting member and are not reflected by the inner wall of the main lens body but directly exit from the second end of the main lens body.

Optionally, a microstructure array is disposed at an end surface of the second end of the main lens body; and

the microstructure array includes a plurality of microstructure units arranged in an array, and a surface of each of the microstructure units away from the light emitting member is a circular-arc face.

Optionally, a light-source utilization ratio of each of the microstructure units is greater than 90%.

Optionally, a spacing between each two neighboring instances of the microstructure units tends to be 1 millimeter.

Optionally, the second quadric surface surrounds the light emitting member, and a focal point of the second quadric surface is located at one side of a first surface of the light emitting member, wherein the first surface of the light emitting member refers to a surface opposite to a light emitting surface of the light emitting member.

Optionally, a distance between a focal point of the second quadric surface and the light emitting member is a first distance, wherein the first distance ranges from 1 millimeter to 4 millimeters.

Optionally, a focal point of the first quadric surface is located at one side of a second surface of the light emitting member, wherein the second surface of the light emitting member refers to a light emitting surface of the light emitting member.

Optionally, there is a second distance between a focal point of the first quadric surface and a second surface of the light emitting member, and the second distance is greater than one third of a distance between the first end and the second end of the main lens body.

Optionally, the lens includes a curved-surface lens and a fixing cavity; and

one end of the fixing cavity is fixed to the first end of the main lens body, the curved-surface lens is fixed to a second end of the fixing cavity, and a convex surface of the curved-surface lens forms the first quadric surface.

In the second aspect, an embodiment of the present disclosure further provides a lens array, wherein the lens array includes the lenses according to any one of the embodiments in the first aspect; and

the plurality of lenses are arranged in a predetermined array, wherein the predetermined array is an array that forms a displaying size of the lens array.

In the third aspect, an embodiment of the present disclosure provides a displaying module, wherein the displaying module includes a lamp panel, a display panel and the lens array according to any one of the embodiments in the second aspect;

the lens array is disposed between the display panel and the lamp panel; and

the display panel covers a top surface of the lens array, a first surface of the lamp panel is disposed at a bottom of the lens array, and the light emitting member is electrically connected to the first surface of the lamp panel.

Optionally, the displaying module further includes a back plate; and

the back plate is disposed on a second surface of the lamp panel, the second surface of the lamp panel refers to a surface of the lamp panel that is opposite to the first surface, and the back plate is configured for controlling the light emitting member electrically connected to the lamp panel to emit light.

Optionally, the displaying module further includes a heat dissipating fin; and

the heat dissipating fin coats a surface of the back plate away from the lamp panel.

Optionally, the display panel includes a main displaying layer and a bottom-layer displaying layer;

the main displaying layer and the bottom-layer displaying layer are in stack, and the bottom-layer displaying layer covers the top surface of the lens array; and

the bottom-layer displaying layer is configured for controlling a brightness of the displaying module, and the main displaying layer is a displaying layer covering a color film.

Optionally, the bottom-layer displaying layer includes a plurality of pixel displaying units, and a brightness of each of the pixel displaying units is controllable.

Optionally, the bottom-layer displaying layer includes monochromatic pixel displaying units, the main displaying layer includes color displaying units, and a ratio of an area occupied by the monochromatic pixel displaying units in the bottom-layer displaying layer to an area occupied by the color pixel displaying units in the main displaying layer is less than 1:4.

Optionally, when all of the plurality of pixel displaying units included by the bottom-layer displaying layer are turned on, the brightness of the displaying module is a maximum brightness value;

when all of the plurality of pixel displaying units included by the bottom-layer displaying layer are turned off, the brightness of the displaying module is a minimum brightness value; and

when some of the plurality of pixel displaying units included by the bottom-layer displaying layer are turned on and some of the pixel displaying units are turned off, the brightness of the displaying module is a brightness value between the maximum brightness value and the minimum brightness value.

In the fourth aspect, an embodiment of the present disclosure provides a displaying device, wherein the displaying device includes the displaying module according to any one of the embodiments in the third aspect.

It can be seen from the above embodiments that, in the embodiments of the present disclosure, because a first quadric surface is disposed in the inner cavity of the main lens body, a second quadric surface is disposed on an inner wall of the main lens body, the first quadric surface is convex toward the first end of the main lens body, and the second quadric surface is convex toward the second end of the main lens body, the light rays emitted by the light emitting member and within the first incident-angle range, after passing through the first quadric surface, can be refracted, and be collimated by and exit from the second end of the main lens body, and the light rays emitted by the light emitting member and within the second incident-angle range, after passing through the second quadric surface, can be reflected on the second quadric surface, and be collimated by and exit from the second end of the main lens body. Further, because the maximum angle value within the first incident-angle range is less than the minimum value within the second incident-angle range, and the first incident-angle range refers to the incident-angle range corresponding to the light rays that are emitted by the light emitting member and are not reflected by the inner wall of the main lens body but directly exit from the second end of the main lens body, all of the light rays emitted by the light emitting member can be modulated and subsequently be collimated and exit, waste of the energy of the light emitting member is avoided, the one-hundred-percent utilization of the light rays is realized.

### BRIEF DESCRIPTION OF THE DRAWINGS

In order to more clearly illustrate the technical solutions of the embodiments of the present disclosure or the prior art, the figures that are required to describe the embodiments or the prior art may be briefly described below. Apparently, the figures that are described below are embodiments of the present disclosure, and a person skilled in the art can obtain other figures according to these figures without paying creative work.

FIG. 1 illustrates a schematic structural diagram of a lens according to an embodiment of the present disclosure;

FIG. 2 illustrates a schematic diagram of the optical-path propagation of a lens according to an embodiment of the present disclosure;

FIG. 3 illustrates a schematic structural diagram of a microstructure array included by a lens according to an embodiment of the present disclosure;

FIG. 4 illustrates a schematic structural diagram of a microstructure according to an embodiment of the present disclosure;

FIG. 5 illustrates a schematic structural diagram of a lens array according to an embodiment of the present disclosure;

FIG. 6 illustrates a schematic diagram of the distribution of lenses of a lens array according to an embodiment of the present disclosure;

FIG. 7 illustrates a schematic structural diagram of a displaying module according to an embodiment of the present disclosure;

FIG. 8 illustrates a schematic structural diagram of a display panel included by a displaying module according to an embodiment of the present disclosure;

FIG. 9 illustrates a schematic diagram of brightness simulation of a lens array according to an embodiment of the present disclosure; and

FIG. 10 illustrates a schematic diagram of intensity section of a lens according to an embodiment of the present disclosure.

### REFERENCE NUMBERS

1: lamp panel; 2: display panel; 3: lens array; 4: back plate; 21: main displaying layer; 22: bottom-layer displaying layer; 31: lens; 311: main lens body; 312: light emitting member; 313: first quadric surface; 314: second quadric surface; 315: microstructure array; 316: fixing cavity; and 3151: microstructure units.

### DETAILED DESCRIPTION

The technical solutions according to the embodiments of the present disclosure may be clearly and completely described below with reference to the drawings according to the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work fall within the protection scope of the present disclosure.

It should be understood that the “one embodiment” or “an embodiment” as used throughout the description means that particular features, structures or characteristics with respect to the embodiments are included in at least one embodiment of the present disclosure. Therefore, the “in one embodiment” or “in an embodiment” as used throughout the description does not necessarily refer to the same embodiment. Furthermore, those particular features, structures or characteristics may be combined in one or more embodiments in any suitable form.

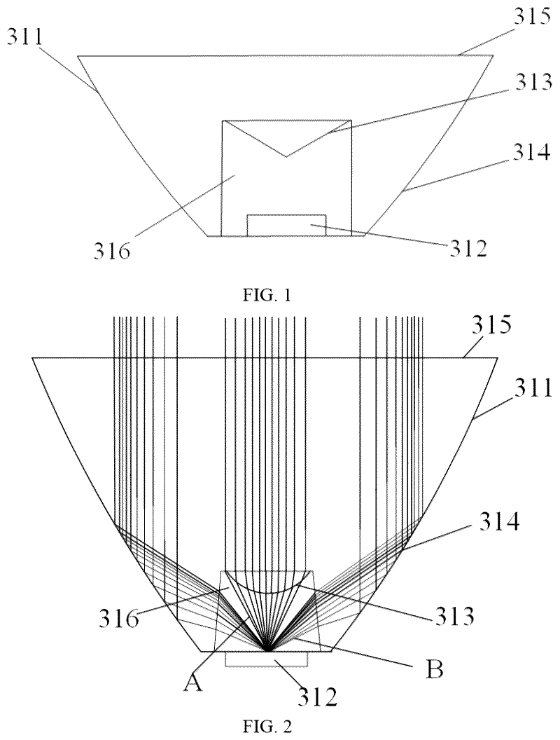

In the first aspect, an embodiment of the present disclosure provides a lens. FIG. 1 illustrates a schematic structural diagram of a lens according to an embodiment of the present disclosure. As shown in FIG. 1, the lens includes a main lens body 311 and a light emitting member 312. The main lens body 311 is a conical housing having an inner cavity, and the light emitting member 312 is disposed at a first end of the main lens body 311. A first quadric surface 313 is disposed in the inner cavity of the main lens body 311. A second quadric surface 314 is disposed on the inner wall of the main lens body 311. The first quadric surface 313 is convex toward the first end of the main lens body 311, and the second quadric surface 314 is convex toward a second end of the main lens body 311, wherein the first end of the main lens body 311 and the second end of the main lens body 311 are two opposite ends of the main lens body 311. and the second end of the main lens body 311 refers to the end of the main lens body 311 where light rays exit. The light rays emitted by the light emitting member 312 and within a first incident-angle range pass through and are refracted by the first quadric surface 313, and subsequently are collimated by and exit from the second end of the main lens body 311, and the incident light rays emitted by the light emitting member 312 and within a second incident-angle range pass through and are reflected by the second quadric surface 314, and subsequently are collimated by and exit from the second end of the main lens body 311, wherein the maximum angle value within the first incident-angle range is less than the minimum value within the second incident-angle range, and the first incident-angle range refers to the incident-angle range corresponding to the light rays that are emitted by the light emitting member 312 and are not reflected by the inner wall of the main lens body but directly exit from the second end of the main lens body.

The main lens body 311 is a cup-shaped housing, generally a conical housing. The main lens body 311 may be a glass reflection cup, and is fabricated mainly by one-step demoulding. If the main lens body 311 is a conical housing, the diameter of the first end of the main lens body 311 is less than the diameter of the second end of the main lens body 311. Accordingly, the light emitting member 312 may be disposed at the first end of the main lens body 311, whereby the light rays emitted by the light emitting member 312 may be exit from the second end of the main lens body 311.

In an embodiment of the present disclosure, in order to increase the collimation degree of the reflected light rays, a first quadric surface 313 is disposed in the inner cavity of the main lens body 311. A second quadric surface 314 is disposed on the inner wall of the main lens body 311. Both of the first quadric surface 313 and the second quadric surface 314 may be any one of quadric surfaces such as a spherical surface, an ellipsoid and an elliptic paraboloid. A quadric surface refers to a curved surface expressed by using a ternary quadratic equation; in other words. a curved surface expressed by using a ternary quadratic equation in a three-dimensional system of coordinate is referred to as a pattern corresponding to a quadric surface.

As shown in FIG. 2, the first quadric surface 313 is convex toward the first end of the lens, and the light emitting member 312 is disposed at the first end of the main lens body 311; in other words, the first quadric surface 313 is convex toward the light emitting surface of the light emitting member 312. Accordingly, the light rays emitted by the light emitting member 312 and within the first incident-angle range, after passing through the first quadric surface 313, can be refracted, and be collimated by and exit from the second end of the main lens body 311. It should be noted that the first incident-angle range refers to the incident-angle range of the light rays that are emitted by the light emitting member 312 and are not reflected by the inner wall of the main lens body 311 but directly exit. The first incident-angle range is determined according to the shape and the size of the inner cavity of the main lens body 311, and is not limited in the embodiments of the present disclosure. It should also be noted that the collimated exiting refers to that, after refracted by the first quadric surface 313, the included angle between the emergent light rays and the axis of the main lens body 311 has been converged within ±15°. The light rays emitted by the light emitting member 312 and within the first incident-angle range are the light rays shown by A in FIG. 2.

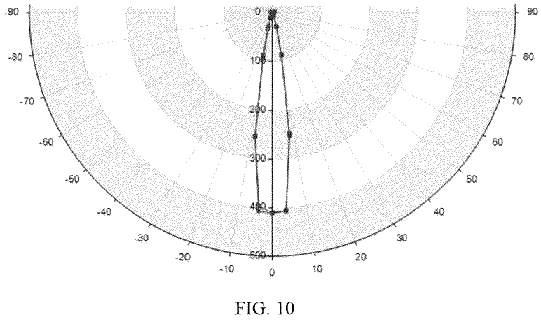

The second quadric surface 314 is convex toward the second end of the lens, and the second end of the main lens body 311 refers to the end of the main lens body 311 where light rays exit; in other words, the second quadric surface 314 is convex toward the light emitting surface of the light emitting member 312. Accordingly, the light rays emitted by the light emitting member 312 and within the second incident-angle range, after passing through the second quadric surface 314, can be reflected on the second quadric surface 314, and be collimated by and exit from the second end of the main lens body 311. It should be noted that the second incident-angle range refers to the other incident-angle ranges than the first incident-angle range. It should also be noted that the collimated exiting refers to that, after reflected by the second quadric surface 314, the included angle between the emergent light rays and the axis of the main lens body 311 has been converged within ±15°. The light rays emitted by the light emitting member 312 and within the first incident-angle range are the light rays shown by A in FIG. 2. The intensity section of the lens is shown in FIG. 10. It can be seen from FIG. 10 that the displaying brightness of the lens is converged within ±15° when perpendicular to the center visual angle by 10%, and the collimation degree of the light rays passing through the lens is increased.

Furthermore, the light emitting member 312 disposed at the first end of the main lens body 311 is a light emitting diode, and the light emitting member 312 is disposed at the axis of the main lens body 311, whereby the light rays emitted by the light emitting member 312 can be distributed at the two sides of the axis of the main lens body 311.

It can be seen from the above embodiments that, in the embodiments of the present disclosure, because a first quadric surface 313 is disposed in the inner cavity of the main lens body 311, a second quadric surface 314 is disposed on the inner wall of the main lens body 311. the first quadric surface 313 is convex toward the first end of the main lens body 311, and the second quadric surface 314 is convex toward the second end of the main lens body 311, the light rays emitted by the light emitting member 312 and within the first incident-angle range, after passing through the first quadric surface 313, can be refracted, and be collimated by and exit from the second end of the main lens body 311, and the light rays emitted by the light emitting member 312 and within the second incident-angle range, after passing through the second quadric surface 314, can be reflected on the second quadric surface 314, and be collimated by and exit from the second end of the main lens body 311. Further, because the maximum angle value within the first incident-angle range is less than the minimum value within the second incident-angle range, and the first incident-angle range refers to the incident-angle range corresponding to the light rays that are emitted by the light emitting member 312 and are not reflected by the inner wall of the main lens body but directly exit from the second end of the main lens body, all of the light rays emitted by the light emitting member 312 can be modulated and subsequently be collimated and exit, which prevents waste of the energy of the light emitting member 312, to realize the one-hundred-percent utilization of the light rays.

The structure of the main lens body 311 and the ranges of the parameters of the first quadric surface 313 and the second quadric surface 314 inside the main lens body 311 is described particularly below. Particularly:

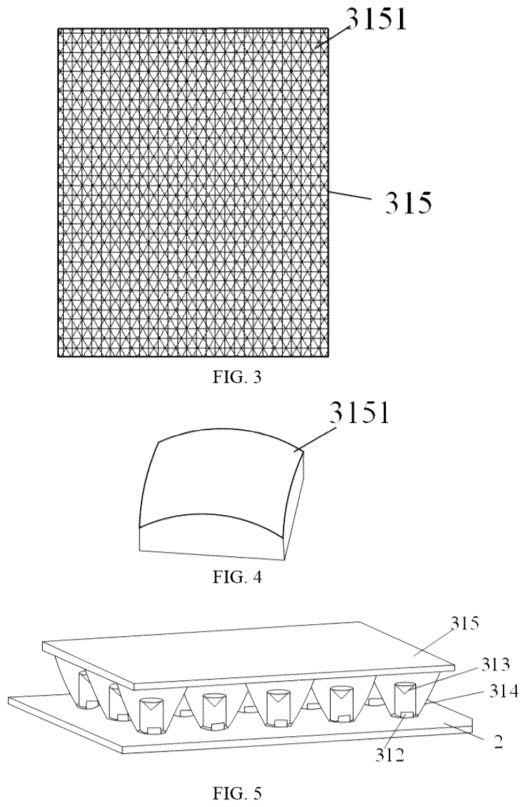

In some embodiments, as shown in FIG. 3 and FIG. 4, a microstructure array 315 is disposed at the end surface of the second end of the main lens body 311, the microstructure array 315 includes a plurality of microstructure units 3151 arranged in an array, and the surface of each of the microstructure units 3151 away from the light emitting member 312 is a circular-arc face.

It should be noted that each of the microstructure units 3151 may be equivalent to a block structure. The top of the block structure is a circular-arc face; in other words, the surface of the block structure away from the light emitting member 312 may be any one of circular-arc faces such as a spherical surface and a ½ circular-arc face, which is not limited in the embodiments of the present disclosure. The circular-arc surface is convex in the direction away from the light emitting member 312. Each two neighboring microstructure units 3151 are closely adhered to each other. When the quantity of the microstructure units 3151 included by the end surface of the second end of the main lens body 311 reaches a certain quantity, the uniformity of the end surface of the second end of the main lens body 311 tends to be consistent.

Optionally, the light-source utilization ratio of each of the microstructure units 3151 is greater than 90%.

It should be noted that, by simulated calculation by using the value of the curvature of the surface of each of the microstructure units 3151 away from the light emitting member 312, the result having the minimum normalized variance can be obtained. When the curvature is 0.4358, the light-source utilization ratio of each of the microstructure units 3151 is greater than 90%. That can increase the probability of the light rays passing through the array of the microstructure units 3151, and increase the displaying brightness of the lens.

Optionally, the spacing between each two neighboring microstructure units 3151 tends to be 1 millimeter.

It should be noted that, as the spacing between each two neighboring microstructure units 3151 tends to be 1 millimeter, the uniformity of the end surface of the second end of the main lens body 311 can reach above 60%.

In some embodiments, the second quadric surface 314 surrounds the light emitting member 312, and the focal point of the second quadric surface 314 is located at one side of a first surface of the light emitting member 312, wherein the first surface of the light emitting member 312 refers to the surface opposite to the light emitting surface of the light emitting member 312.

It should be noted that the second quadric surface 314 is an elliptic paraboloid, and the second quadric surface 314 surrounds the light emitting member 312. Accordingly, as the focal point of the second quadric surface 314 is located at one side of a first surface of the light emitting member 312, it can be ensured that the incident light rays emitted by the light emitting member 312 and within the second incident-angle range can exit from the second quadric surface 314. In other words, when the focal point of the second quadric surface 314 is located at the bottom of the light emitting member 312, it can be ensured that all of the incident light rays emitted by the light emitting member 312 and within the second incident-angle range can knock the quadric surface, which prevents waste of the energy of the light emitting member 312.

Optionally, the distance between the focal point of the second quadric surface 314 and the light emitting member 312 is a first distance, wherein the first distance ranges from 1 millimeter to 4 millimeters.

It should be noted that, as the distance between the focal point of the second quadric surface 314 and the light emitting member 312 is 1 millimeter to 4 millimeters, it can be further ensured that the incident light rays emitted by the light emitting member 312 and within the second incident-angle range can exit from the second quadric surface 314. As an example, the distance between the focal point of the second quadric surface 314 and the light emitting member 312 is 2 millimeters, the curved-surface coefficient of the second quadric surface 314 is −1.22, and the curvature is 0.35. Accordingly, the angle of the light rays emitted by the light emitting member 312 and reaching the second quadric surface 314 and the included angle between the collimation-exiting light rays and the normal can be equal, to further increase the collimation degree of the light rays reflected by the second quadric surface 314.

In some embodiments, the focal point of the first quadric surface 313 is located at one side of a second surface of the light emitting member 312, wherein the second surface of the light emitting member 312 refers to the light emitting surface of the light emitting member 312.

It should be noted that, because the focal point of the first quadric surface 313 is located at one side of a second surface of the light emitting member 312, there is a certain distance between the light emitting member 312 and the first quadric surface 313. Accordingly, the light rays emitted by the light emitting member 312 can firstly pass through the cavity between the light emitting member 312 and the first quadric surface 313, enter the first quadric surface 313 within the first incident-angle range, and subsequently be refracted via the second quadric surface 314. Because, when light obliquely enters another medium from air, the angle of refraction is smaller than the incident angle, the propagation direction of the light rays can be changed. When the distance between the focal point of the first quadric surface 313 and the second surface of the light emitting member 312 is a certain numerical value, the light rays exiting from the second quadric surface 314 can be collimated and exit.

Optionally, there is a second distance between the focal point of the first quadric surface 313 and a second surface of the light emitting member 312, and the second distance is greater than one third of the distance between the first end and the second end of the main lens body 311.

It should be noted that the distance between the focal point of the first quadric surface 313 and the second surface of the light emitting member 312 is greater than one third of the distance between the first end and the second end of the main lens body 311. Therefore, it can be ensured that the angle of the reflector reaching the first quadric surface 313 is maintained at a certain numerical value; in other words, the angle of the light rays reaching the first quadric surface 313 may be modulated by using the distance between the focal point of the first quadric surface 313 and the second surface of the light emitting member 312, to ensure that the light rays exiting from the second quadric surface 314 can be collimated and exit. It should also be noted that the distance between the focal point of the first quadric surface 313 and the second surface of the light emitting member 312 is determined according to the distance between the first end and the second end of the main lens body 311. For example, if the distance between the first end and the second end of the main lens body 311 is 7 millimeters, the distance between the focal point of the first quadric surface 313 and the second surface of the light emitting member 312 is 3 millimeters. The distance between the focal point of the first quadric surface 313 and the second surface of the light emitting member 312 is not limited in the embodiments of the present disclosure.

In some embodiments, the lens includes a curved-surface lens and a fixing cavity 316. One end of the fixing cavity 316 is fixed to the first end of the main lens body 311, the curved-surface lens is fixed to a second end of the fixing cavity 316, and the convex surface of the curved-surface lens forms the first quadric surface 313.

It should be noted that the fixing cavity 316, the curved-surface lens and the main lens body 311 may be formed by integral injection molding. The fixing cavity 316 is formed between the light emitting member 312 and the main lens body 311, and subsequently the fixing cavity 316 is configured to fix the curved-surface lens, and the fixing cavity 316 is configured to propagate the incident light rays emitted by the light emitting member 312 and within the first incident-angle range. Furthermore, because of the existence of the fixing cavity 316, the incident light rays emitted by the light emitting member 312 and within the second incident-angle range, when passing through the cavity wall of the fixing cavity 316, are also refracted to a certain extent. If the thickness of the cavity wall is negligible, the refraction of the incident light rays emitted by the light emitting member 312 and within the second incident-angle range when passing through the cavity wall of the fixing cavity 316 can also be negligible, and does not affect the effect of reflection of the light rays by the second quadric surface 314.

It can be seen from the above embodiments that, in the embodiments of the present disclosure, because a first quadric surface 313 is disposed in the inner cavity of the main lens body 311, a second quadric surface 314 is disposed on the inner wall of the main lens body 311. the first quadric surface 313 is convex toward the first end of the main lens body 311, and the second quadric surface 314 is convex toward the second end of the main lens body 311, the light rays emitted by the light emitting member 312 and within the first incident-angle range, after passing through the first quadric surface 313, can be refracted, and be collimated by and exit from the second end of the main lens body 311, and the light rays emitted by the light emitting member 312 and within the second incident-angle range, after passing through the second quadric surface 314, can be reflected on the second quadric surface 314, and be collimated by and exit from the second end of the main lens body 311. Further, because the maximum angle value within the first incident-angle range is less than the minimum value within the second incident-angle range, and the first incident-angle range refers to the incident-angle range corresponding to the light rays that are emitted by the light emitting member 312 and are not reflected by the inner wall of the main lens body but directly exit from the second end of the main lens body, all of the light rays emitted by the light emitting member 312 can be modulated and subsequently be collimated and exit, which prevents waste of the energy of the light emitting member 312, to realize the one-hundred-percent utilization of the light rays.

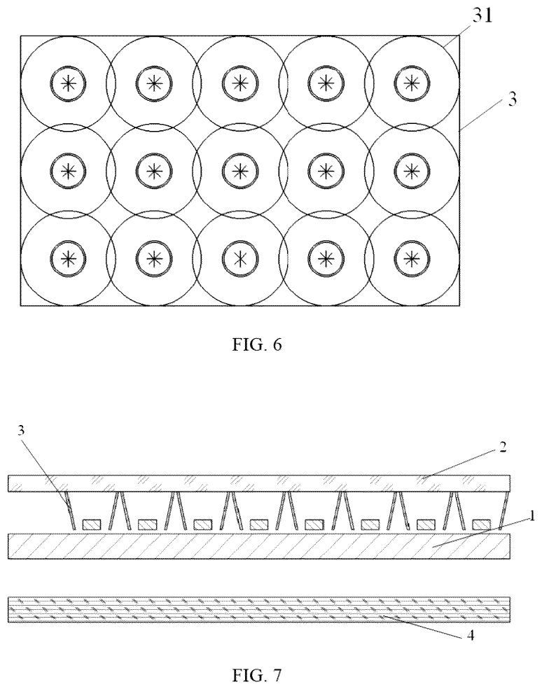

In the second aspect, as shown in FIG. 5 and FIG. 6, an embodiment of the present disclosure further provides a lens array, wherein the lens array includes a plurality of the lens 31 according to any one of the embodiments in the first aspect. The plurality of lenses 31 are arranged in a predetermined array, wherein the predetermined array is an array that forms the displaying size of the lens array.

It should be noted that the predetermined array is an array that satisfies the displaying size of the lens array. For example, the displaying size of the lens array is a displaying size of 45 millimeters×75 millimeters, and accordingly the lenses 31 may be arranged in an array of 5×3; in other words, the lens array has 3 rows and 3 columns. As shown in FIG. 9, according to the final result of the simulation of the lens array, the average brightness is 2610 thousands of nits. the power consumption is 12 W, and the uniformity is 56%, which is increased by 2.8 times as compared with the optical efficiency of the conventional solutions of reflection cups. The predetermined array of the lens array is determined according to the displaying size of the lens array, and is not limited in the embodiments of the present disclosure.

It can be seen from the above embodiments that, in the embodiments of the present disclosure, because the plurality of lenses 31 are arranged in a predetermined array, while all of the light rays emitted by the light emitting members of all of the lenses 31 can be modulated and subsequently be collimated and exit, to realize the one-hundred-percent utilization of the light rays, the displaying brightness of the lens array can be increased, whereby the effect of the lens array is improved.

In the third aspect, as shown in FIG. 7, an embodiment of the present disclosure further provides a displaying module, wherein the displaying module includes a lamp panel 1, a display panel 2 and the lens array 3 in the second aspect. The lens array 3 is disposed between the display panel 2 and the lamp panel 1. The display panel 2 covers a top surface of the lens array 3, and the light emitting member 312 is electrically connected to the first surface of the lamp panel 1.

It should be noted that, because the lens array 3 is disposed between the display panel 2 and the lamp panel 1, the display panel 2 covers a top surface of the lens array, and the light emitting member 312 is electrically connected to the first surface of the lamp panel 1, the lamp panel I can be configured to control the light emitting member 312 to emit light, which subsequently transmits the lenses 31 and is displayed on the display panel 2. Because the displaying brightness of the lens array 3 is increased, the effect of displaying of the display panel 2 is also improved, which facilitates to improve the overall effect of displaying of the displaying module.

In some embodiments, the displaying module further includes a back plate 4. The back plate 4 is disposed on a second surface of the lamp panel 1, wherein the second surface of the lamp panel 1 refers to the surface of the lamp panel 1 that is opposite to the first surface.

It should be noted that the back plate 4 is a circuit board that can control the light emitting member 312 to emit light. By using the back plate 4 to control separately the light emitting members 312 of the lenses of the lens array 3, local light regulating on the displaying module is realized, to adapt for different application scenes, whereby the usage of the displaying module is not restricted.

Optionally, the displaying module further includes a heat dissipating fin, and the heat dissipating fin coats the surface of the back plate 4 away from the lamp panel 1. Accordingly, the heat of the back plate 4 can be dissipated by using the heat dissipating fin, which facilitates to prolong the service life of the displaying module.

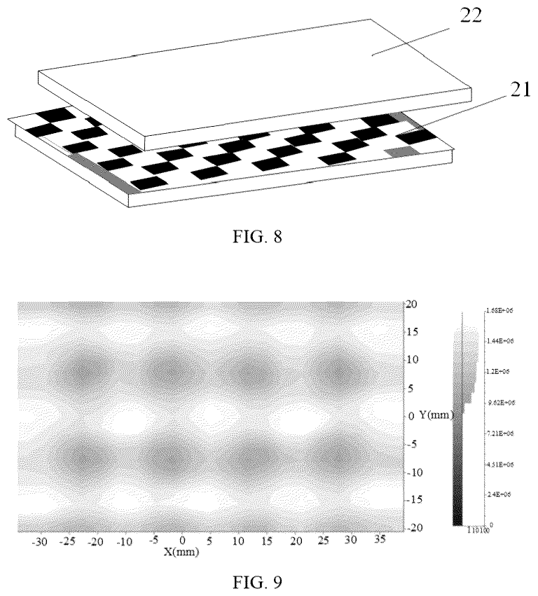

Optionally, as shown in FIG. 8, the display panel 2 includes a main displaying layer 21 and a bottom-layer displaying layer 22. The main displaying layer 21 and the bottom-layer displaying layer 22 are in stack, and the bottom-layer displaying layer 22 covers the top surface of the lens array. The bottom-layer displaying layer 22 is configured for controlling the brightness of the displaying module, and the main displaying layer 21 is a displaying layer covering a color film.

It should be noted that, by stacking the main displaying layer 21 and the bottom-layer displaying layer 22, and covering the top surface of the lens array with the bottom-layer displaying layer 22, the contrast of the displaying module can be improved. In other words, the brightness of the displaying module can be controlled by using the bottom-layer displaying layer 22, i.e., controlling the proportion between the highest brightness and the lowest brightness of the displaying module. By using the double-panel displaying module formed by the main displaying layer 21 and the bottom-layer displaying layer 22 according to the embodiment of the present disclosure, the effect of at least 500,000:1 of the static contrast of the displaying module can be realized.

Further, the bottom-layer displaying layer 22 includes a plurality of pixel displaying units, and the brightness of each of the pixel displaying units is controllable.

It should be noted that the quantity of the pixel displaying units may be adjusted according to the size of the displaying module. As an example, if the size of the displaying module is 65 inches, then the quantity of the pixel displaying units can reach 2000000.

Accordingly, the effect from the full turning-on of the pixel displaying units of the bottom-layer displaying layer 22 to the local darkening or even turning-off of the bottom-layer displaying layer 22 can be realized, whereby the darkening and lightening of each of the pixel displaying units can be controlled to be turned on and turned off, to enable the displayed frames of the displaying module to be more exquisite.

Particularly, when all of the plurality of pixel displaying units included by the bottom-layer displaying layer 22 are turned on, the brightness of the displaying module is a maximum brightness value. When all of the plurality of pixel displaying units included by the bottom-layer displaying layer 22 are turned off, the brightness of the displaying module is a minimum brightness value. When some of the plurality of pixel displaying units included by the bottom-layer displaying layer 22 are turned on and some of the pixel displaying units are turned off, the brightness of the displaying module is a brightness value between the maximum brightness value and the minimum brightness value. Accordingly, when the quantity of the plurality of pixel displaying units included by the bottom-layer displaying layer 22 is sufficiently large, the range of the regulatable brightness of the displaying module can be further enlarged. whereby the darkening and lightening of each of the pixel displaying units can be controlled to be turned on and turned off, to enable the displayed frames of the displaying module to be more exquisite.

Furthermore, the bottom-layer displaying layer 22 includes monochromatic pixel displaying units, the main displaying layer 21 includes color displaying units, and the ratio of the area occupied by the monochromatic pixel displaying units in the bottom-layer displaying layer to the area occupied by the color pixel displaying units in the main displaying layer is less than 1:4.

As an example, when the ratio of the area occupied by the monochromatic pixel displaying units in the bottom-layer displaying layer to the area occupied by the color pixel displaying units in the main displaying layer is 1:25, as compared with 1:4, the transmittance can be correspondingly increased by 25.6%. That further indicates that, because of the factors such as the pixel black-matrix region, to further increase the corresponding ratio has little effect on the increasing of the transmittance, and therefore the transmittance can be increased by using the ratio of the area occupied by the monochromatic pixel displaying units in the bottom-layer displaying layer to the area occupied by the color pixel displaying units in the main displaying layer, which can realize a more exquisite displaying function, greatly improve the displayed image quality, and reduce the power consumption of the displaying module. Furthermore, the bottom-layer displaying layer 22 is the displayed part of the frames, covers the displaying of the color film, and can realize the displaying of different colors, which further enriches the application scenes of the displaying module.

It can be seen from the above embodiments that, because the lens array 3 is disposed between the display panel 2 and the lamp panel 1, the display panel 2 covers a top surface of the lens array, and the light emitting member 312 is electrically connected to the first surface of the lamp panel 1, the lamp panel I can be configured to control the light emitting member 312 to emit light, which subsequently transmits the lenses and is displayed on the display panel 2. Because the displaying brightness of the lens array 3 is increased, the effect of displaying of the display panel 2 is also improved, which facilitates to improve the overall effect of displaying of the displaying module.

In the fourth aspect, an embodiment of the present disclosure further provides a displaying device, wherein the displaying device includes the displaying module according to any one of the embodiments in the third aspect.

It should be noted that the displaying device may be a mobile displaying device such as a mobile phone, a tablet personal computer, a notebook computer, a palmtop, an onboard displaying device, a wearable device, an ultra-mobile personal computer (UMPC), a netbook and a personal digital assistant (PDA), or a non-mobile displaying device such as a personal computer (PC), a television set (TV), a teller machine and a self-service machine, which is not particularly limited in the embodiments of the present disclosure. The advantageous effects of the displaying device are the same as those of the displaying module stated above, and are not discussed further in the embodiments of the present disclosure. As an example, when the displaying device is a vehicle head-up display, because of the brightness increasing, a more exquisite projected displaying is realized, and a better visual effect can be reached.

It should be noted that the embodiments of the description are described in the mode of progression, each of the embodiments emphatically describes the differences from the other embodiments, and the same or similar parts of the embodiments may refer to each other.

Although alternative embodiments of the embodiments of the present disclosure have been described, once a person skilled in the art has known the essential inventive concept, he may make further variations and modifications on those embodiments. Therefore, the appended claims are intended to be interpreted as including the alternative embodiments and all of the variations and modifications that fall within the scope of the embodiments of the present disclosure.

Finally, it should also be noted that, herein, relation terms such as first and second are merely intended to distinguish one entity from another entity, and that does not necessarily require or imply that those entities have therebetween any such actual relation or order. Furthermore, the terms “include”, “include” or any variants thereof are intended to cover non-exclusive inclusions, so that articles or terminal devices that include a series of elements do not only include those elements, but also include other elements that are not explicitly listed, or include the elements that are inherent to such articles or terminal devices. Unless further limitation is set forth, an element defined by the wording “including a . . . ” does not exclude additional same element in the article or terminal device including the element.

The technical solutions of the present disclosure have been described in detail above. The principle and the embodiments of the present disclosure are described herein with reference to the particular examples. Moreover, for a person skilled in the art, according to the principle and the implementations of the present disclosure, the particular embodiments and the range of application may be varied. In conclusion, the contents of the description should not be understood as limiting the present disclosure.

1. A lens, wherein the lens comprises a main lens body and a light emitting member;
the main lens body is a conical housing having an inner cavity, and the light emitting member is disposed at a first end of the main lens body;
a first quadric surface is disposed in the inner cavity of the main lens body; a second quadric surface is disposed on an inner wall of the main lens body;
the first quadric surface is convex toward the first end of the main lens body, and the second quadric surface is convex toward a second end of the main lens body, wherein the first end of the main lens body and the second end of the main lens body are two opposite ends of the main lens body, and the second end of the main lens body refers to one end of the main lens body where light rays exit; and
light rays emitted by the light emitting member and within a first incident-angle range pass through and are refracted by the first quadric surface, and subsequently are collimated by and exit from the second end of the main lens body, and incident light rays emitted by the light emitting member and within a second incident-angle range pass through and are reflected by the second quadric surface, and subsequently are collimated by and exit from the second end of the main lens body, wherein a maximum angle value within the first incident-angle range is less than a minimum value within the second incident-angle range, and the first incident-angle range refers to an incident-angle range corresponding to light rays that are emitted by the light emitting member and are not reflected by the inner wall of the main lens body but directly exit from the second end of the main lens body.

2. The lens according to claim 1, wherein a microstructure array is disposed at an end surface of the second end of the main lens body; and
the microstructure array comprises a plurality of microstructure units arranged in an array, and a surface of each of the microstructure units away from the light emitting member is a circular-arc face.

3. The lens according to claim 2, wherein a light-source utilization ratio of each of the microstructure units is greater than 90%.

4. The lens according to claim 2, wherein a spacing between each two neighboring microstructure units tends to be 1 millimeter.

5. The lens according to claim 1, wherein the second quadric surface surrounds the light emitting member, and a focal point of the second quadric surface is located at one side of a first surface of the light emitting member, wherein the first surface of the light emitting member refers to a surface opposite to a light emitting surface of the light emitting member.

6. The lens according to claim 1, wherein a distance between a focal point of the second quadric surface and the light emitting member is a first distance, wherein the first distance ranges from 1 millimeter to 4 millimeters.

7. The lens according to claim 1, wherein a focal point of the first quadric surface is located at one side of a second surface of the light emitting member, wherein the second surface of the light emitting member refers to a light emitting surface of the light emitting member.

8. The lens according to claim 6, wherein there is a second distance between a focal point of the first quadric surface and a second surface of the light emitting member, and the second distance is greater than one third of a distance between the first end and the second end of the main lens body.

9. The lens according to claim 1, wherein the lens comprises a curved-surface lens and a fixing cavity; and
one end of the fixing cavity is fixed to the first end of the main lens body, the curved-surface lens is fixed to a second end of the fixing cavity, and a convex surface of the curved-surface lens forms the first quadric surface.

10. A lens array, wherein the lens array comprises a plurality of the lenses according to claim 1; and
the plurality of lenses are arranged in a predetermined array, wherein the predetermined array is an array that forms a displaying size of the lens array.

11. A displaying module, wherein the displaying module comprises a lamp panel, a display panel and the lens array according to claim 10;
the lens array is disposed between the display panel and the lamp panel; and
the display panel covers a top surface of the lens array, a first surface of the lamp panel is disposed at a bottom of the lens array, and the light emitting member is electrically connected to the first surface of the lamp panel.

12. The displaying module according to claim 11, wherein the displaying module further comprises a back plate; and
the back plate is disposed on a second surface of the lamp panel, the second surface of the lamp panel refers to a surface of the lamp panel that is opposite to the first surface, and the back plate is configured for controlling the light emitting member electrically connected to the lamp panel to emit light.

13. The displaying module according to claim 12, wherein the displaying module further comprises a heat dissipating fin; and
the heat dissipating fin coats a surface of the back plate away from the lamp panel.

14. The displaying module according to claim 11, wherein the display panel comprises a main displaying layer and a bottom-layer displaying layer;
the main displaying layer and the bottom-layer displaying layer are in stack, and the bottom-layer displaying layer covers the top surface of the lens array; and
the bottom-layer displaying layer is configured for controlling a brightness of the displaying module, and the main displaying layer is a displaying layer covering a color film.

15. The displaying module according to claim 14, wherein the bottom-layer displaying layer comprises a plurality of pixel displaying units, and a brightness of each of the pixel displaying units is controllable.

16. The displaying module according to claim 14, wherein the bottom-layer displaying layer comprises monochromatic pixel displaying units, the main displaying layer comprises color displaying units, and a ratio of an area occupied by the monochromatic pixel displaying units in the bottom-layer displaying layer to an area occupied by the color pixel displaying units in the main displaying layer is less than 1:4.

17. The displaying module according to claim 14, wherein when all of the plurality of pixel displaying units comprised by the bottom-layer displaying layer are turned on, the brightness of the displaying module is a maximum brightness value;
when all of the plurality of pixel displaying units comprised by the bottom-layer displaying layer are turned off, the brightness of the displaying module is a minimum brightness value; and
when some of the plurality of pixel displaying units comprised by the bottom-layer displaying layer are turned on and some of the pixel displaying units are turned off, the brightness of the displaying module is a brightness value between the maximum brightness value and the minimum brightness value.

18. A displaying device, wherein the displaying device comprises the displaying module according to claim 11.

19. The displaying device according to claim 18, wherein the displaying module further comprises a back plate; and
the back plate is disposed on a second surface of the lamp panel, the second surface of the lamp panel refers to a surface of the lamp panel that is opposite to the first surface, and the back plate is configured for controlling the light emitting member electrically connected to the lamp panel to emit light.

20. The displaying device according to claim 19, wherein the displaying module further comprises a heat dissipating fin; and
the heat dissipating fin coats a surface of the back plate away from the lamp panel.
